(19) United States
(12) Patent Application Publication
(10) Pub. No.: US 2026/0302697 A1
(43) Pub. Date: Oct. 1, 2026

(54) UNIVERSAL MOUNTING SYSTEM FOR MONITORING DEVICES

(71) Applicant: Infinity Building Solutions, LLC, Suwanee, GA (US)

(72) Inventors: Tyson Baker, Cumming, GA (US); Matthew Gambeski, Cumming, GA (US); Eric Chang, Buford, GA (US)

(21) Appl. No.: 19/097,603

(22) Filed: Apr. 1, 2025

(51) Int. Cl. H01R 13/73; H01R 13/512; H01R 24/64

(52) U.S. Cl. CPC H01R 13/73; H01R 13/512; H01R 24/64

(57) ABSTRACT

A universal mounting system for monitoring devices is provided. The universal mounting system includes a housing that defines a recessed region. The universal mounting system also includes a first magnet, and a second magnet disposed in the recessed region. The universal mounting system also includes a mounting bracket that is disposed in the recessed region that can mate with a monitoring device couplable to the universal mounting system. The universal mounting system further includes a fastener boss that is also disposed within the recessed region that can also mate with the monitoring device, and a communication interface board that is also disposed within the recessed region and which includes a plurality of electrical connectors.

### TECHNICAL FIELD

The present disclosure relates generally to mounting solutions for monitoring devices. Specifically, the embodiments of the present disclosure are related to universal mounting system for attaching various types of monitoring devices to server housings, pallets, racks, and other types of storage units or shelves.

### BACKGROUND

Conventional mounting solutions for monitoring devices are often mounted directly to an electrical box, which can often times be in less-than-ideal locations. Wall mount solutions can also be difficult to install on non-standard surfaces like a server housing or metal cabinets. In some instances, the mounting solution may be installed in locations where the monitoring devices are blocked by equipment or airflow obstructions, leading to inaccurate readings. Some mounting solutions may not fit all types or brands of monitoring devices, making retrofitting or upgrades difficult. In other instances, the mounting solutions may be too large or bulky and may interfere with housing, cabling, or airflow.

Therefore, there is a need for a versatile mounting solution for monitoring devices that provides easy repositioning, ease of attachment, and minimal interference with equipment in most environments.

### BRIEF DESCRIPTION OF THE DRAWINGS

FIG. 1 illustrates a mounting system coupled to a monitoring device in accordance with an embodiment of the present disclosure.

FIG. 2 illustrates an internal view of the universal mounting system in accordance with the principles of the present disclosure.

FIG. 3 illustrates a backside view of the universal mounting system in accordance with the principles of the present disclosure.

FIG. 4 illustrates an example scenario in which the universal mounting system and the monitoring device may be used in accordance with the principles of the present disclosure.

FIG. 5 illustrates another example scenario in which the universal mounting system and the monitoring device may be used in accordance with the principles of the present disclosure.

The drawings are provided for purposes of illustration only and merely depict example embodiments of the disclosure. The drawings are provided to facilitate understanding of the disclosure and shall not be deemed to limit the breadth, scope, or applicability of the disclosure. The use of the same reference numerals indicates similar, but not necessarily the same or identical components. Different reference numerals may be used to identify similar components. Various embodiments may utilize elements or components other than those illustrated in the drawings, and some elements and/or components may not be present in various embodiments. The use of singular terminology to describe a component or element may, depending on the context, encompass a plural number of such components or elements and vice versa.

### DETAILED DESCRIPTION

The various embodiments of the universal mounting system described herein advantageously provide an easy and efficient solution for placing monitoring devices within an environment. The embodiments are described in detail herein to enable one of ordinary skill in the art to practice the universal mounting system, although it is to be understood that other embodiments may be utilized and that logical changes may be made without departing from the scope of the disclosure. Reference is made herein to the accompanying drawings illustrating some embodiments of the disclosure, in which use of the same reference numerals indicates similar or identical items. Throughout the disclosure, depending on the context, singular and plural terminology may be used interchangeably.

The meanings of the terms used herein will be apparent to one of ordinary skill in the art or will become apparent to one of ordinary skill in the art upon review of the detailed description when taken in conjunction with the several drawings and the appended claims.

Embodiments of the present disclosure provide a universal mounting system for monitoring devices. The universal mounting system may include a housing defining a recessed region, a first magnet disposed in the recessed region, and a second magnet disposed in the recessed region. The universal mounting system may further include a mounting bracket disposed in the recessed region. The mounting bracket may be configured to mate with a first portion of a monitoring device couplable to the universal mounting system. The universal mounting system further includes a fastener boss disposed within the recessed region, the fastener boss configured to mate with a second portion of the monitoring device, and a communication interface board disposed within the recessed region, the communication interface board including a plurality of electrical connectors.

Other embodiments of the present disclosure provide a system that includes a monitoring device and a universal mounting system that is releasably coupled to the monitoring device. The universal mounting system further includes a housing defining a recessed region and plurality of components disposed within the recessed region. The plurality of components include a first fastener boss, a first magnet, a second magnet, a mounting bracket attached to a second fastener boss, and a communication interface board. The communication interface board may further include a first connector and a second connector, and the communication interface board may be electrically coupled to the monitoring device.

Some other embodiments of the present disclosure provide a system that includes a first mounting system coupled to a first monitoring device, a second mounting system coupled to a second monitoring device, and a third mounting system coupled to a third monitoring device. The system further includes a first cable connected between a first connector of the first mounting system and a first connector of the second mounting system, a second cable connected between a second connector of the second mounting system and a first connector of the third mounting system, and a third cable connected between a second connector of the third mounting system and a controller. Each of the first, the second, and the third mounting systems further includes a housing, a plurality of magnets disposed in the housing, a mounting bracket disposed in the housing, and a communication interface board disposed in the housing.

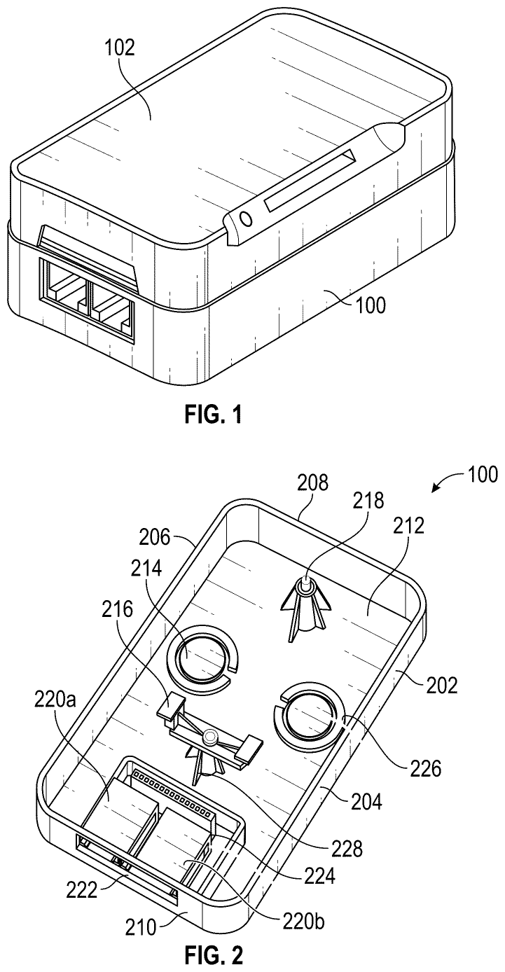

FIG. 1 illustrates a mounting system 100 coupled to a monitoring device 102 in accordance with an embodiment of the present disclosure. The monitoring device 102 may include various types of devices such as remote annunciators, indicators, alarms or sensors that measure temperature, relative humidity, carbon dioxide, volatile organic compounds, particulate matter, or any other parameters within an environment. The mounting system 100 is designed to accommodate various types of monitoring devices 102 with minimal modifications thus providing a versatile solution to attaching monitoring devices to various types of surfaces such as server housing and metal cabinets. In an embodiment, the monitoring device 102 may be snap-fitted to the mounting system 100 such that the monitoring device 102 can be easily removed and replaced without having to change the mounting system 100. The mounting system 100 is designed to be removably attached to various types of surfaces. This allows easy removal and/or repositioning of the universal mounting system 100 and the monitoring device 102 that is attached to the universal mounting system 100. In an embodiment, the universal mounting system 100 may be manufactured using materials that include plastic or the like. While the monitoring device 102 and the mounting system 100 are shown here as two different components that are couplable to each other, in some embodiments, both the monitoring device 102 and the mounting system 100 can be integrated into a single device.

FIG. 2 illustrates an internal view of the universal mounting system 100 in accordance with an embodiment of the present disclosure. The universal mounting system 100 may include a housing 202. The housing is defined by a first member 204, a second member 206, a third member 208, and a fourth member 210. In an embodiment, the first member 204 is parallel to the second member 206 and the third member 208 is parallel to the fourth member 210. In another embodiment, the first member 204 is orthogonal to the third member 208 and the fourth member 210. In yet another embodiment, the second member 206 is orthogonal to the third member 208 and the fourth member 210. In an embodiment, the first member 204, the second member 206, the third member 208, and the fourth member 210 together define a recessed region 212. The recessed region 212 houses multiple components that are used to couple a monitoring device to the housing 202 and electrically connect the monitoring device to another monitoring device. Each of the first member 204, the second member 206, the third member 208, and the fourth member 210 may have a height and the height defines a depth of the recessed region 212.

The recessed region 212 may include one or more magnets 214 that are disposed in a magnet housing 226. The magnets 214 may be used to adhere the housing 202 to another surface such as that of a server housing or a rack. In an embodiment, the housing 202 may include more than two magnets 214. In an embodiment, the magnets 214 may be placed along a single line, such as a line parallel to a side wall of the housing 202. In other embodiments, the magnets may be placed in other patterns such as rectangular, circular, polygonal, or the like. In an embodiment, the magnets 214 may be circular in shape. In other embodiments, the magnets 214 may be of other shapes such as rectangular, polygonal, elongated, horseshoe, ring, cylindrical, cube, spherical, arc, triangle, pyramid, countersunk, cone, dome, or the like. In some embodiments, the magnets 214 may be natural magnets such as lodestone or magnetite. In other embodiments, the magnets 214 may be artificial or man-made magnets that include, but are not limited to neodymium magnets, samarium-cobalt (SmCo) magnets, alnico magnets, ceramic/ferrite magnets, or flexible magnets. In yet other embodiments, the magnets 214 may include temporary magnets, electromagnets, bonded magnets, injection-molded magnets, magnet arrays (e.g., Halbach Arrays), anisotropic magnets, etc. The magnets 214 allow the housing 202 to be removably adhered to a complimentary surface that includes iron, steel, nickel, cobalt, magnetite, ferritic stainless steel, martensitic stainless steel, or the like. In an embodiment the pull force on each of the magnets 214 is about 16 pounds. However, the pull force of the magnets 214 can be adjusted based on the thickness of the material between the surface of the housing 202 and the surface to which the housing 202 is attached. In an embodiment, where there is more than one magnet 214 in the housing 202, one or more of those magnets may be of different types. Thus, different types of magnets may be used within a single housing 202.

The recessed region 212 may further include a mounting bracket 216. The mounting bracket 216 may be used to couple to a portion of the monitoring device to hold the monitoring device housing. The mounting bracket 216 may be sized and shaped to conform to the associated monitoring device housing so that the mounting bracket 216 can properly attach to the monitoring device housing to secure the monitoring device housing. In an embodiment, the mounting bracket 216 may be attached to the housing 202 via a fastener and a first fastener boss 228. The mounting bracket 216 may include snaps, clips, or other type of fastening mechanism to couple with the housing of the monitoring device 102. The housing 202 may further include a second fastener boss 218 that may also be used to secure the monitoring device housing to the housing 202. In an embodiment, the second fastener boss 218 may be configured to accept a screw that may be used to couple the monitoring device housing to the housing 202. In an embodiment, the first fastener boss 228 and the second fastener boss 218 may be placed on either side of the magnets 214 such that the magnets 214 are disposed in between the first fastener boss 228 and the second fastener boss 218. In an embodiment, the two magnets 214 may be separated by a distance along the same line such that the first magnet is closer to the first member 204 and the second magnet is closer to the second member 206. In an embodiment, both the magnets 214 may be identical in structure, composition and shape. In other embodiments, the two magnets 214 may have different structure, composition and/or shape. This configuration may allow a secure method for attaching the monitoring device to the housing 202.

The recessed region 212 may further include a communication interface board 224 that is proximate to the fourth member 210. The communication interface board may include a couple or communication ports 220a and 220b. In an embodiment, the housing 202 may include two communication ports 220a and 220b. In other embodiments, the housing 202 may include more than two communication ports. In an embodiment, the communication port 220a and/or 220b may be one of a RJ-45 connector, a RS-232 connector, a RS-422 connector, a RS-485 connector, a USB connector, a CAN connector, a Modbus connector, a Profibus connector, or the like. In an embodiment, both the communication ports 220a and 220b may be of the same type. In other embodiments, the housing 202 may include two different types of communication ports 220a and 220b (e.g., a RJ-45 and a RS-422). In an embodiment, the communication ports 220a and 220b are electrically coupled to each other such that data and power can flow from between one communication port 220a and the other communication port 220b. In other embodiments, the communication interface board 224 may also support any commonly known wireless communication protocols. In such instances, presence of communication ports 220 may be optional or the communication ports 220a and 220b may be used as a back-up in the event that the wireless communication is unavailable for any reason. The fourth member 210 may include an opening 222 that allows access to the communication ports 220a and 220b. In an embodiment, the mounting bracket 216 may be disposed between the communication ports 220a and 220b and the magnets 214. Although the housing 202 is illustrated as being rectangular in structure in FIG. 2, one skilled in the art will realize that the housing 202 may be designed based on the size and shape of the monitoring device to which the housing 202 is to be connected. For instance, if the monitoring device is circular in shape, the housing 202 will also be circular in shape in order to couple to the monitoring device. In that instance, the various components disposed withing the housing 202 and the recessed region 212 will be placed based on the shape and size of the housing 202.

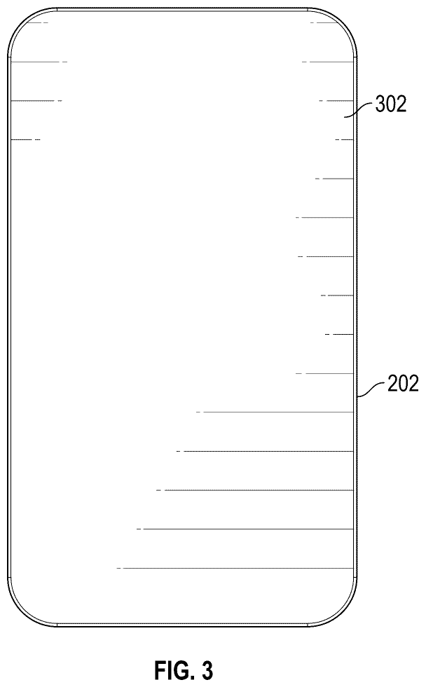

FIG. 3 illustrates a backside view of the universal mounting system 100 in accordance with an embodiment of the present disclosure. The housing 202 may include a back surface 302. When the universal mounting system 100 is attached to an external surface, the back surface 302 is in physical contact with the external surface. In an embodiment, the back surface 302 is planar so that it can securely adhere to the external surface. The magnets 214 cause the back surface 302 to remain securely attached to the external surface. In some embodiments, the back surface 302 of the housing 202 may have an attachment mechanism in addition to or in lieu of the magnets 214. The attachment mechanism may include hook and loop fasteners, low-tack adhesive, tabs or the like to attach the housing 202 to the external surface. In some embodiments, the magnet housing 226 may extend to the back surface 302 such that a portion of the magnets 214 is visible from the back side.

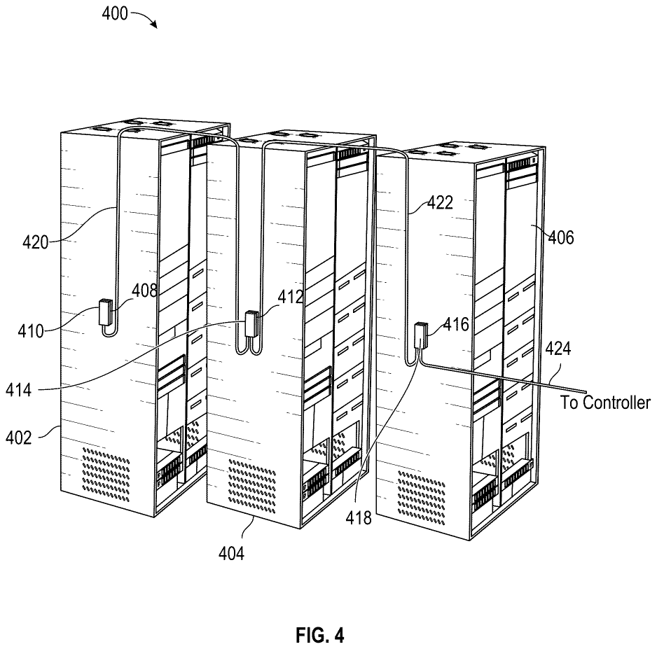

FIG. 4 illustrates an example scenario 400 in which the universal mounting system and the monitoring device may be used in accordance with an embodiment of the present disclosure. The universal mounting system can be used to daisy-chain two or more monitoring devices within an environment. As illustrated in FIG. 4, the environment may include multiple server housings 402, 404, and 406. Each of the server housings includes a universal mounting system and an associated monitoring device. For instance, a first mounting system 408 is coupled with a first monitoring device 410 and removably attached to a surface of the server rack 402. A second mounting system 412 is coupled with a second monitoring device 414 and removably attached to a surface of a second server rack 404. A third mounting system 416 is coupled with a third monitoring device 418 and removably attached to a surface of a third server rack 406. The multiple universal mounting systems 408, 412, and 416 having associated the monitoring devices 410, 414, and 418 are connected together in a daisy-chain configuration. In this instance, multiple monitoring devices 410, 414, and 418 are connected in a series, one after another, rather than each monitoring device having a direct, individual connection to a controller. Only the last monitoring device 418 in the daisy-chain has a direct connection to the controller. The controller may receive data from each of the monitoring devices 410, 414, and 418 and further process the data based on its programming.

As noted above, the monitoring devices 410, 414, and 418 are connected sequentially, via the respective universal mounting systems 408, 412, and 416 where the communication and/or power output of one monitoring device feeds into the input of the next monitoring device, via the communication interface of the respective universal mounting system. For instance, a single cable runs between the monitoring devices 410, 414, and 418, avoiding the need for multiple cables routed back to the controller. As illustrated, a first cable 420 is connected between a first connector of the first universal mounting system 408 and a first connector of the second universal mounting system 412. A second cable 422 is connected between a second connector of the second universal mounting system 412 and a first connector of the third universal mounting system 416. A third cable 424 is connected between a second connector of the third universal mounting system 416 and the controller.

As explained above, the universal mounting systems 408, 412, and 416 all support multiple communication protocols. For example, the communication protocols supported may include RS-485 or RS-422 serial communication protocols, a 1-wire protocol, and/or a controller area network (CAN) protocol. Further, the universal mounting systems 408, 412, and 416 can be removably connected to any portion or any surface of the respective server housings 402, 404, and 406. In other embodiments, the universal mounting systems 408, 412, and 416 can be placed at any location along the height, width, or depth of the respective server housings 402, 404, and 406. In other embodiments, the universal mounting systems 408, 412, and 416 may be removably attached to either an external surface or an internal surface of the respective server housings 402, 404, and 406. In some embodiments, all of the monitoring devices 410, 414, and 418 can be of the same type (e.g., temperature sensors). In other embodiments, some or all of the monitoring devices 410, 414, and 418 may be of a different type (e.g., humidity sensor, temperature sensor, and smoke sensor).

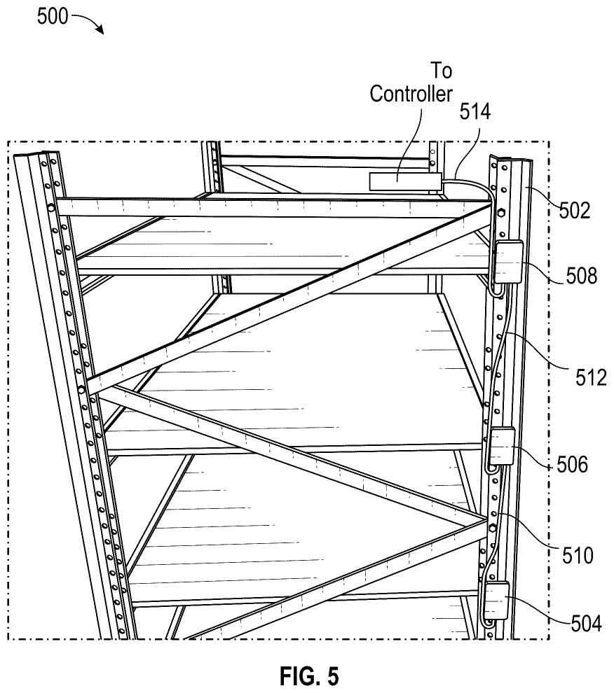

FIG. 5 illustrates another scenario 500 in which the universal mounting system and the monitoring device may be used in accordance with another embodiment of the present disclosure. In scenario 500, multiple universal mounting systems 504, 506, and 508 are all removably attached to a same storage unit 502. Each of the universal mounting systems 504, 506, and 508 is coupled with a respective monitoring device (not separately shown in FIG. 5). While FIG. 5 shows the universal mounting systems 504, 506, and 508 as being attached to the same surface of the storage unit, that need not be the case. Each of the universal mounting systems 504, 506, and 508 can be attached to a different surface of the storage unit 502. The scenario 500 illustrates a case where the universal mounting systems 504, 506, and 508 are used for monitoring certain parameters at different heights of the storage unit 502. Depending on what items is placed in each of the shelves of the storage unit 502, a different type of monitoring device may be used to monitor the specific desired parameter. Each of the universal mounting systems 504, 506, and 508 is daisy-chained to work in conjunction with each other. For example, a first cable 510 is connected between a first connector of the universal mounting system 504 and a first connector of the universal mounting 506. A second cable is connected between a second connector of the universal mounting system 506 and a first connector of the universal mounting system 508. A third cable 514 is connected between a second connector of the universal mounting system 508 and a controller (not shown). In an embodiment, each of the universal mounting systems 504, 506, and 508 may be coupled to a same type of monitoring device. In other embodiments, each of the universal mounting systems 504, 506, and 508 may be coupled to a different type of monitoring device.

The present disclosure provides details on a specific type of universal mounting system, but one skilled in the art will realize that other types of universal mounting system may also be manufactured using the systems and methods provided in this disclosure.

One or more illustrative embodiments of the disclosure have been described above. The above-described embodiments are merely illustrative of the scope of this disclosure and are not intended to be limiting in any way. Accordingly, variations, modifications, and equivalents of the embodiments disclosed herein are also within the scope of this disclosure.

While the present disclosure has been described with reference to a number of embodiments, it will be understood by those skilled in the art that the invention is not limited to such disclosed embodiments. Rather, the disclosure can be modified to incorporate any number of variations, alterations, substitutions, or equivalent arrangements not described herein, but which are commensurate with the spirit and scope of the disclosure. Additionally, while various embodiments of the disclosure have been described, it is to be understood that aspects of the disclosure may include only some of the described embodiments. Accordingly, the disclosure is not to be seen as limited by the foregoing description but is only limited by the scope of the appended claims.

What is claimed is:

1. A universal mounting system comprising:
a housing defining a recessed region;
a first magnet disposed in the recessed region;
a second magnet disposed in the recessed region;
a mounting bracket disposed in the recessed region, the mounting bracket configured to mate with a first portion of a monitoring device couplable to the universal mounting system;
a fastener boss disposed within the recessed region, the fastener boss configured to mate with a second portion of the monitoring device; and
a communication interface board disposed within the recessed region, the communication interface board including a plurality of electrical connectors.

2. The universal mounting system of claim 1, wherein the housing includes a first member, a second member, a third member and a fourth member, wherein:
the first member is parallel to the second member; and
the third member is parallel to the fourth member.

3. The universal mounting system of claim 2, wherein:
the first member is orthogonal to the third member and the fourth member; and
the second member is orthogonal to the third member and the fourth member.

4. The universal mounting system of claim 1, wherein the first magnet and the second magnet are disposed along a line parallel to a side wall of the housing.

5. The universal mounting system of claim 1, wherein the first magnet and the second magnet are located between the mounting bracket and the fastener boss.

6. The universal mounting system of claim 1, wherein the mounting bracket is located between the communication interface board and the first and the second magnets.

7. The universal mounting system of claim 1, wherein the first magnet is disposed in a first magnet housing and the second magnet is disposed in a second magnet housing.

8. The universal mounting system of claim 1, wherein the plurality of connectors include a first connector and a second connector, wherein each of the first connector and the second connector supports a serial communication protocol.

9. The universal mounting system of claim 8, wherein the first connector and the second connector are of a same type.

10. A system comprising:
a monitoring device; and
a universal mounting system releasably coupled to the monitoring device, wherein the universal mounting system comprises a housing defining a recessed region and a plurality of components disposed within the recessed region, wherein the plurality of components include:
a first fastener boss;
a first magnet;
a second magnet;
a mounting bracket attached to a second fastener boss; and
a communication interface board, the communication interface board including a first connector and a second connector and wherein the communication interface board is electrically coupled to the monitoring device.

11. The system of claim 10, wherein the first magnet and the second magnet are disposed along a line parallel to a side wall of the housing.

12. The system of claim 10, wherein the first connector and the second connector both support one or more serial communication protocols.

13. The system of claim 10, wherein the first magnet and the second magnet are disposed between the mounting bracket and the first fastener boss.

14. The system of claim 10, wherein the first fastener boss is configured to mate with a first portion of the monitoring device and the mounting bracket is configured to mate with a second portion of the monitoring device.

15. The system of claim 10, wherein the mounting bracket is sized and shaped to couple with a housing of the monitoring device.

16. The system of claim 10, wherein the first connector or the second connector includes a RJ-45, a RS-422, or a RS-485 connector.

17. The system of claim 10, wherein the mounting bracket is disposed between the communication interface board and the first and the second magnet.

18. A system comprising:
a first mounting system coupled to a first monitoring device;
a second mounting system coupled to a second monitoring device;
a third mounting system coupled to a third monitoring device;
a first cable connected between a first connector of the first mounting system and a first connector of the second mounting system;
a second cable connected between a second connector of the second mounting system and a first connector of the third mounting system; and
a third cable connected between a second connector of the third mounting system and a controller, wherein each of the first, the second, and the third mounting systems include:
a housing;
a plurality of magnets disposed in the housing;
a mounting bracket disposed in the housing; and
a communication interface board disposed in the housing.

19. The system of claim 18, wherein the plurality of magnets are configured to removably adhere the respective mounting systems to an external surface.

20. The system of claim 18, wherein:
the first mounting system, the second mounting system, and the third mounting system are each removably coupled to a respective storage unit; or
the first mounting system, the second mounting system, and the third mounting system are each removably coupled to the same storage unit.
